(19) United States
(12) Patent Application Publication
(10) Pub. No.: US 2009/0033431 A1
(43) Pub. Date: Feb. 5, 2009

(54) Oscillation Circuit

(75) Inventors: Hiroki Yamashita, Hachioji (JP); Koji Fukuda, Fuchu (JP); Ryo Nemoto, Saitama (JP); Hisaaki Kanai, Yokohama (JP); Keiichi Yamamoto, Yamato (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi, Ltd.

(21) Appl. No.: 12/182,171

(22) Filed: Jul. 30, 2008

(30) Foreign Application Priority Data
Aug. 1, 2007 (JP) 2007-200351

(51) Int. Cl. H03K 3/03

(52) U.S. Cl. 331/57

(57) ABSTRACT

The present invention provides a highly accurate oscillation circuit. For example, the oscillation circuit includes plural ring oscillator units RO1 and RO2 including inverter circuits IV of an odd number of stages, and an adding unit ADD that adds signals of output nodes RO_{—}01 and RO_{—}02 of the RO1 and RO2. It outputs an addition result of the ADD from an output node OSC_O as a clock signal, and feeds the output node OSC_O back to input nodes RO_I1 and RO_I2 of the RO1 and RO2. Thereby, for example, when each of delay times of the RO1 and RO2 disperses based on a normal distribution of standard deviation σ, the dispersion of a clock signal obtained from the OSC_O can be confined to σ/\sqrt{2}.

### CLAIM OF PRIORITY

The present application claims priority from Japanese patent application JP 2007-200351 filed on Aug. 1, 2007, the content of which is hereby incorporated by reference into this application.

### FIELD OF THE INVENTION

The present invention relates to an oscillation circuit, and more particularly to technology effectively applied to an oscillation circuit such as a PLL (Phase Locked Loop) circuit that includes a ring oscillator.

### BACKGROUND OF THE INVENTION

For example, in JP-A 2004-146900, a clock generating circuit is described that generates a clock signal by adding the outputs of two independent ring oscillators. In this construction, since a jitter component of the ring oscillators has a dispersion of normal distribution, the jitter component is reduced by adding their outputs.

### SUMMARY OF THE INVENTION

In recent years, as semiconductor products become faster, more accurate oscillation circuits have been required. Among oscillation circuits, there are various systems such as those that use delay time of inverter circuits (so-called ring oscillators), and those that use LC resonance. Of them, a ring oscillator can be formed at low costs using CMOS process, and is available in a wide range of frequencies. Therefore, it is widely used in various product fields including PC (Personal Computer), server devices, and communication network equipments.

However, the ring oscillator has a problem in that jitter components caused by noises are larger in comparison with the LC resonance system and the like. FIG. 10 is an explanatory diagram showing the cause of jitter components in a ring oscillator studied as a premise of the present invention. FIG. 10 shows a ring oscillator that includes inverter circuits IV of five stages, and can set an oscillation frequency by a variable voltage source VC. Each inverter circuit IV is constituted by a CMOS circuit that includes a PMOS transistor MP and an NMOS transistor MN, and the like (S101).

In the ring oscillator, delay time of the CMOS circuit is controlled by current amounts, and thereby an oscillation frequency is controlled. However, since current noises corresponding to frequencies are contained in currents flowing through the MP and MN (S102), random phase fluctuations (that is, jitter components) occur in its oscillation output (S103). The current noises are an overlap of 1/f noises that occur in a PN junction and the like, and become larger for lower frequencies, and thermal noises that occur in a dispersion resistance unit and the like, and are independent from frequencies. It is known that the distribution of jitters caused by current noises follows a normal distribution (S104).

To reduce the jitter components, it is conceivable to use technology as shown in JP-A 2004-146900. However, the construction of JP-A 2004-146900 cannot necessarily reduce jitter components. The present invention has been made in view of such circumstances, and one of its objects is to provide a highly accurate oscillation circuit. The aforementioned and other objects and novel characteristics of the present invention will become apparent from the description of this specification and the accompanying drawings.

The typical disclosures of the invention will be described in brief as follows.

An oscillation circuit of the present invention includes N (N≧2) delay circuit units each including cascade-connected inverter circuits of an odd number of stages between an input node and an output node, an adding unit that adds signals of the respective output nodes of the delay circuit units, and a feedback loop that feeds a result of the addition in the adding unit in common back to the respective input nodes of the delay circuit units. Use of this construction makes it possible to confine the dispersion of a clock signal obtained from an output (addition result) of the adding unit to σ/\sqrt{N} when delay time of the N delay circuit units disperses based on a normal distribution of standard deviation σ. As a result, a highly accurate clock signal of small dispersion can be generated.

The above-described adding unit that feeds an addition result in common back to the respective input nodes can be realized, for example, by connecting in common the output nodes of the delay circuit units. By the way, in a circuit construction (JP-A 2004-146900) that connects outputs of plural ring oscillators to input terminals of an adder and takes out a single clock output from the adder, an addition result is not fed back to the ring oscillators. An oscillation circuit disclosed in the present patent application includes circuit means provided in loops of plural ring oscillators that add signals of each loop and again reflect an addition result in the each loop, thereby making it possible to reduce a dispersion of oscillation outputs.

Making connections common produces another possible effect of making an area smaller in comparison with the case of additionally providing an adding circuit. The inverter circuits of an odd number of stages are preferably CMOS inverter circuits and differential amplifier circuits formed by CMOS process. While use of CMOS process can facilitate and miniaturize manufacturing process, jitter components of a clock signal due to 1/f noises of MOS transistors, thermal noises, and the like may increase. By using the oscillation circuit of the present invention, an increase in the jitter components can be curbed.

An effect obtained by a typical disclosure of the present patent application is, in brief, the realization of a highly accurate oscillation circuit.

### BRIEF DESCRIPTION OF THE DRAWINGS

FIG. 1 is a block diagram showing an example of the construction of an oscillation circuit of a first embodiment of the present invention;

FIG. 2 is a circuit diagram showing an example of the construction of a ring oscillator unit in the oscillation circuit of FIG. 1;

FIG. 3 is a circuit diagram showing an example of the construction of an adding unit in the oscillation circuit of FIG. 1;

FIG. 4 is a circuit diagram showing another example of the construction of an adding unit in the oscillation circuit of FIG. 1;

FIG. 5 is a circuit diagram showing an example of a construction with the circuit of FIG. 2 applied to a ring oscillator unit in the oscillation circuit of FIG. 4;

FIG. 6 shows the operation principle of the oscillation circuit of FIG. 5, wherein FIG. 6A is an explanatory drawing showing the distribution of jitter components of each ring oscillator unit, and FIG. 6B is an image drawing of a waveform appearing in an output node of the oscillation circuit;

FIG. 7 shows the operation principle of the oscillation circuit of FIG. 5, and is an explanatory drawing showing the distribution of jitter components appearing in an output node of the oscillation circuit;

FIG. 8 is a circuit diagram showing an example of the construction of an oscillation circuit of a second embodiment of the present invention;

FIG. 9 is a block diagram showing an example of the construction of an oscillation circuit of a third embodiment of the present invention; and

FIG. 10 is an explanatory diagram showing the cause of jitter components in a ring oscillator studied as a premise of the present invention.

### DETAILED DESCRIPTION OF THE PREFERRED EMBODIMENTS

Hereinafter, embodiments of the present invention will be described in detail with reference to the accompanying drawings. In all drawings for describing the embodiments, as a rule, identical members are assigned identical reference numerals, and duplication of descriptions is omitted. In embodiments below, when conveniently necessary, although each embodiment is split into plural sections or embodiments for description, unless otherwise specified, they are not independent from each other, and one is in a relation of partial or all variations, details, additional description, and the like of the other. In embodiments below, the number of elements (including count, number, amount, range, and the like), when referred to, is not limited to a specific number but may be equal to or greater than, or less than a specific value, unless otherwise specified, and except when apparently limited to a specific number in principle.

Furthermore, in embodiments below, it goes without saying that the components (including element steps and the like) are not necessarily required, unless otherwise specified, and except when apparently required in principle. Likewise, in embodiments below, when reference is made to the shape, positional relation, and the like of components, those that are substantially close or similar to the shape and the like are included, unless otherwise specified, and except when considered apparently different in principle. The same is also true for the above-described numbers and range.

### First Embodiment

FIG. 1 is a block diagram showing an example of the construction of an oscillation circuit of a first embodiment of the present invention. An oscillation circuit OSC shown in FIG. 1 includes two ring oscillator units (delay circuit units) RO1 and RO2 and an adding unit ADD. RO1 and RO2 include an identical circuit construction, and each includes inverter circuits IV of an odd number of stages. An adding unit ADD is connected to an output node RO_O1 of RO1 and an output node RO_O2 of RO2, and the result of adding these signals is outputted to an output node OSC_O of the OSC. Furthermore, the output node OSC_O is connected to an input node RO_I1 of RO1 and an input node RO_I2 of RO2. Thereby, a feedback loop is formed in RO1 and RO2.

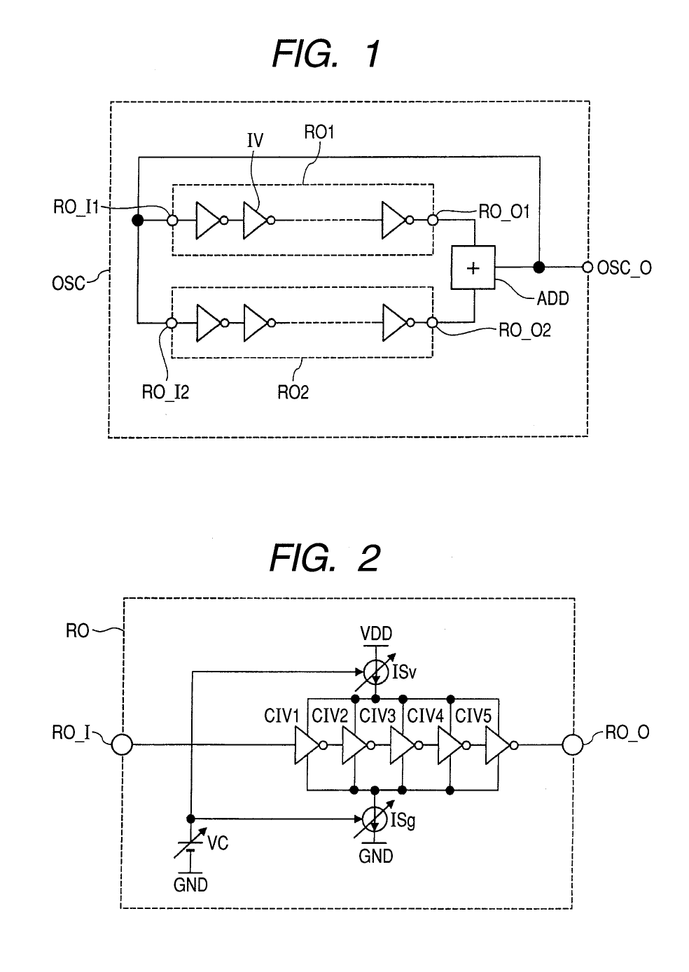

FIG. 2 is a circuit diagram showing an example of the construction of a ring oscillator unit in the oscillation circuit of FIG. 1, and corresponds to each of RO1 and RO2 of FIG. 1. A ring oscillator unit RO (delay circuit unit) shown in FIG. 2 includes cascade-connected CMOS inverter circuits CIV1 to CIV5 of an odd number of stages (five stages here) between the input node RO_I and the output node RO_O, variable current sources ISv and ISg, variable voltage source VC. The ISv and ISg each supply an operation current proportional or inversely proportional to the variable voltage source VC to the CIV1 to CIV5. ISv is inserted between PMOS transistors included in CIV1 to CIV5 (not shown) and a power voltage VDD, and ISg is inserted between NMOS transistors (not shown) included in the CIV1 to CIV5 and ground voltage GND.

Therefore, current amounts of the CIV1 to CIV5 are controlled according to voltage values in the variable voltage source VC, and according to this, propagation delay time from the RO_I to RO_O is controlled. Although the variable current sources ISv and ISg are provided here in both the VDD side and the GND side, any one of them may be provided.

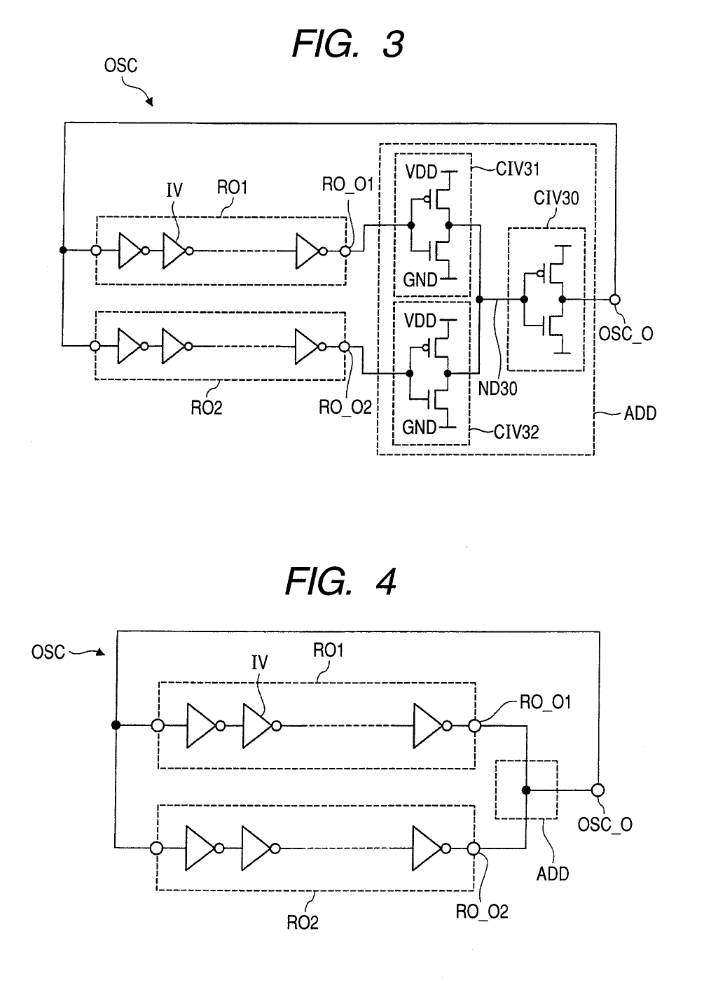

FIG. 3 is a circuit diagram showing an example of the construction of an adding unit in the oscillation circuit of FIG. 1. In FIG. 3, the adding unit ADD includes, for example, three CMOS inverter circuits CIV30 to CIV32. The CIV31 input an output node RO_O1 of the ring oscillator unit RO1, and the CIV32 inputs an output node RO_O2 of the ring oscillator unit RO2. The output of the CIV31 and CIV32 are connected in common and inputted to the CIV 30. The output of the CIV30 becomes an output node OSC_O of the oscillation circuit OSC, and the node is fed back to the input of the RO1 and RO2. According to the adding unit ADD, the output of RO1 and the output of RO2 are added in the common output node ND30 of the CIV31 and CIV32. A result of the addition is reflected to drive the CIV30, and an obtained clock signal is fed back.

FIG. 4 is a circuit diagram showing another example of the construction of the addition unit in the oscillation circuit of FIG. 1. In FIG. 4, no special circuit is provided as an adding unit ADD, the output node RO_O1 of RO1 and the output node RO_O2 of RO2 are connected directly to the output node OSC_O of OSC. By thus realizing the adding unit ADD only by wiring, a circuit area can be reduced.

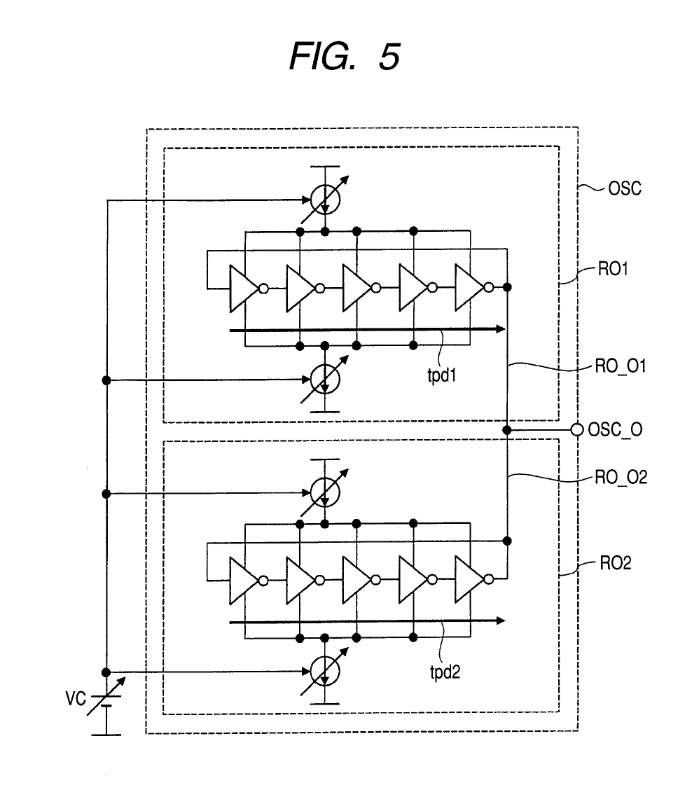

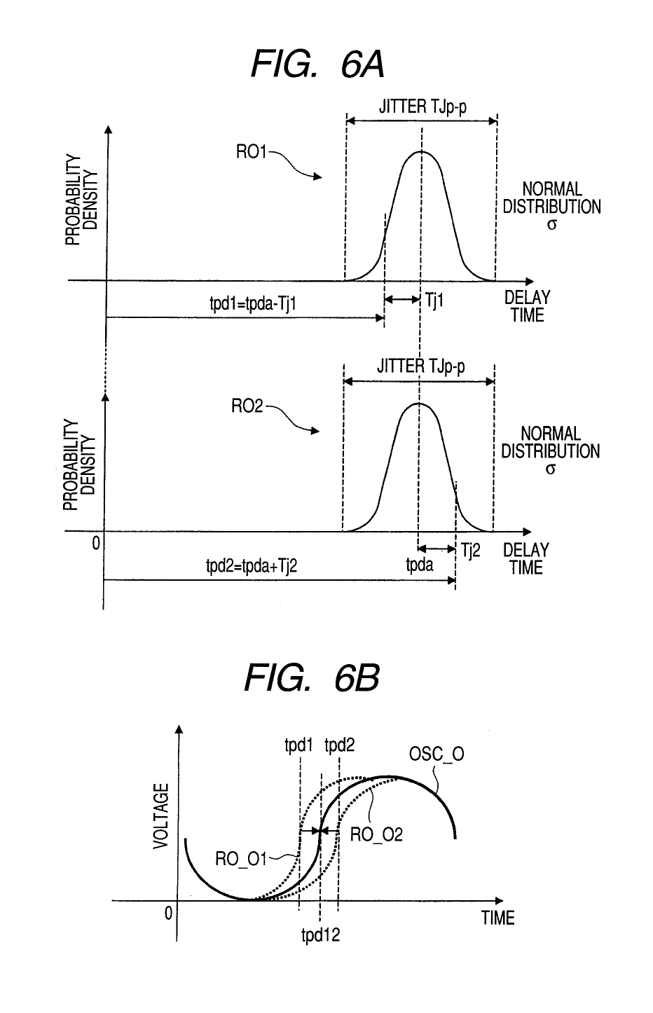

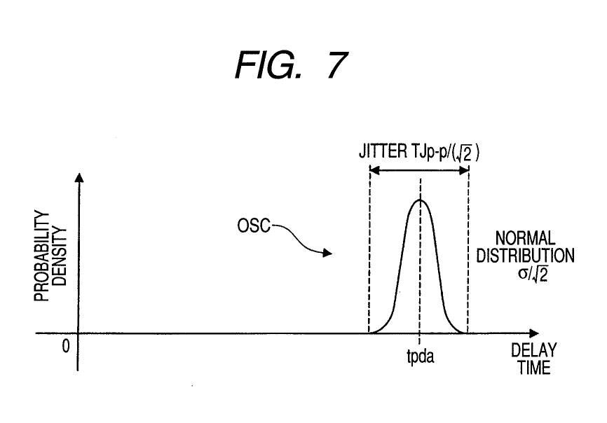

The following describes an operational principle of an oscillation circuit of this embodiment. FIG. 5 is a circuit diagram showing an example of a construction with the circuit of FIG. 2 applied to a ring oscillator unit in the oscillation circuit of FIG. 4. Here, the operational principle is described using the oscillation circuit OSC of FIG. 5 as an example. When propagation delay times of the ring oscillator unit RO1 and the ring oscillator unit RO2 in FIG. 5 are defined as tpd1 and tpd2, respectively, tpd1 and tpd2 form a dispersion distribution as shown in FIG. 6A.

FIG. 6 shows the operation principle of the oscillation circuit of FIG. 5, wherein FIG. 6A is an explanatory drawing showing the distribution of jitter components of ring oscillator units RO1 and RO2, and FIG. 6B is an image drawing of a waveform appearing in the output node OSC_O of the oscillation circuit. As shown in FIG. 6A, the propagation delay times tpd1 and tpd2 each have the dispersion of normal distribution having standard deviation σ centering on average propagation delay time tpda. A dispersion width determined according to the σ is a jitter component TJp-p.

As shown in FIG. 6A, for example, in a certain clock cycle, when tpd1=tpda−Tj1, and tpd2=tpda+Tj2 (Tj1, Tj2>0), a waveform as shown in FIG. 6B is obtained. That is, a clock waveform occurs in the output node RO_02 of RO2 after a clock waveform occurring in the output node RO_O1 of RO1 in a delayed manner, with the result that a clock waveform produced by adding (averaging) them is obtained in the output node OSC_O. Effective propagation delay time tpd12 of the clock waveform of this output node OSC_O is close to average propagation delay time tpda, and effectively, dispersion is reduced.

FIG. 7 shows the operation principle of the oscillation circuit of FIG. 5, and is an explanatory drawing showing the distribution of jitter components appearing in an output node of the oscillation circuit.

Generally, when n normal distributions of average value μ and standard deviation σ exist, it is known that the average value of the “N average values” is μ, and a standard deviation (that is, called a standard error) consequent on it is σ/\sqrt{N}. Therefore, propagation delay time tpd12 in the output node OSC_O of the oscillation circuit, as shown in FIG. 7, has the dispersion of normal distribution having standard deviation σ/\sqrt{2}, centering on average propagation delay time tpda.

As described above, by using the oscillation circuit of the this embodiment, in comparison with the case of generating a clock waveform by one ring oscillator, its jitter component can be reduced to 1/\sqrt{2}. Theoretically, the jitter component can be reduced by increasing the number of ring oscillator units RO. However, in terms of a circuit area and power consumption, about two are desired.

In the construction described in Patent Document 1 described previously, the outputs of ring oscillators independent of each other are added, and a feedback loop from the result of the addition is not provided as it is in FIG. 1 and the like. In this case, for example, as described in FIG. 6A, the average propagation delay time of RO1 and RO2 does not necessarily become a same value (tpda). As described in FIG. 10, particularly, when a ring oscillator is constructed using MOS circuits, since its 1/f noise becomes large in a low frequency band, the average propagation delay time of RO1 and RO2 may significantly deviate. Therefore, since normal distributions having different average values respectively are added and averaged, jitter components cannot necessarily be reduced.

### Second Embodiment

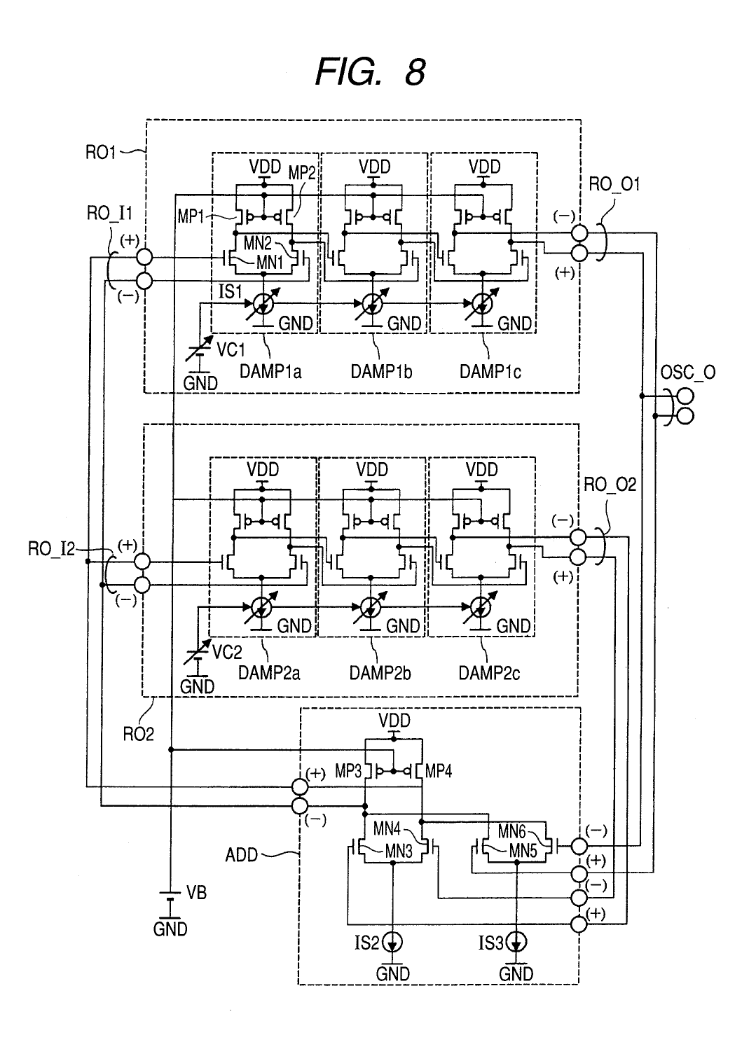

In the second embodiment, an example of a construction with a differential amplifier circuit applied to each circuit block of the construction example of FIG. 1 described previously is described. FIG. 8 is a circuit diagram showing an example of the construction of an oscillation circuit of the second embodiment of the present invention. In FIG. 8, the ring oscillator unit (delay circuit unit) R01 includes cascade-connected differential amplifier circuits DAMP1a, DAMP1b, and DAMP1c of three stages. The ring oscillator unit (delay circuit unit) R02 also includes cascade-connected differential amplifier circuits DAMP2a, DAMP2b, and DAMP2c of three stages.

DAMP1a to DAMP1c and DAMP2a to DAMP2c each include NMOS transistors MN1 and MN2 forming a differential pair (transistor pair), PMOS transistors MP1 and MP2 connected to the drains of MN1 and MN2, respectively, and a variable current source IS1 connected between a common source of MN1 and MN2 and ground voltage GND. The MP1 and MP2 function as load circuits of a differential pair, their gates are connected in common to a bias voltage VB, their sources are connected in common to a power voltage VDD, and the drain of the MP 1 is connected to the drain of the MN1, and the drain of the MP 2 to the drain of the MN2.

When the gate of MN1 is input (non-inverted input) and the gate of MN2 is input (inverted input), the drain of MN1 (MP1) becomes (−) output (inverted output) and the drain of MN2 (MP2) becomes (+) output (non-inverted output). In the ring oscillator unit RO1, the (−) output and (+) output of DAMP1a are connected to the (+) input and (−) input of DAMP1b, and the (−) output and (+) output of DAMP1b are connected to the (+) input and (−) input of DAMP1c. In the ring oscillator unit RO2, likewise, the (−) output and (+) output of DAMP2a are connected to the (+) input and (−) input of DAMP2b, and the (−) output and (+) output of DAMP2b are connected to the (+) input and (−) input of DAMP2c.

Therefore, in the RO1, when input ‘H’ and ‘L’ are inputted to the gates of MN1 and MN2 of DAMP1a, respectively, ‘L’ and ‘H’ with polarities inverted are outputted from the drains of MN1 and MN2 of DAMP1c through differential amplifier circuits of three stages. In the RO2, likewise, when input ‘H’ and ‘L’ are inputted to the gates of MN1 and MN2 of DAMP2a, respectively, ‘L’ and ‘H’ with polarities inverted are outputted from the drains of MN1 and MN2 of DAMP2c through differential amplifier circuits of three stages.

A current proportional or inversely proportional to voltage values of the variable voltage source VC1 flows through the variable current source IS1 included in the DAMP1a to DAMP1c, and a current proportional or inversely proportional to voltage values of the variable voltage source VC2 flows through the variable current source IS1 included in the DAMP2a to DAMP2c. By setting a voltage value of the variable voltage sources VC1 and VC2, the propagation delay time of RO1 and RO2 can be set, and thereby an oscillation frequency can be set. Although VC1 and VC2 are individually provided here, actually, they may be made common because a same voltage value is set.

In FIG. 8, the adding unit ADD includes NMOS transistors MN3 to MN6, PMOS transistors MP3 and MP4, and constant current sources IS2 and IS3. The MN3 and MN4 form a differential pair (transistor pair), their sources are connected in common, the drain of MN3 is connected to the drain of MP3, and the drain of MN4 is connected to the drain of MP4. Likewise, the MN5 and MN6 form a differential pair, their sources are connected in common, the drain of MN5 is connected to the drain of MP3 (MN3), and the drain of MN6 is connected to the drain of MP4 (MN4). The IS2 is provided between the common source of MN3 and MN4, and ground voltage GND, and the IS3 is provided between the common source of MN5 and MN6, and GND. The MP3 and MP4 function as load circuits common to each differential pair (MN3 and MN4, and MN5 and MN6), the gates of MP3 and MP4 are connected to a bias voltage VB, and the sources of MP3 and MP4 are connected to the power voltage VDD.

When the gates of MN3 and MN5 are (+) input, and the gates of MN4 and MN6 are (−) input, the common drains of MN3, MN5, and MP3 become (−) output, and the common drains of MN4, MN6, and MP4 become (+) output. (−) output from DAMP1c is inputted to (+) input of MN5, and (+) output from DAMP1c is inputted to (−) input of MN6. On the other hand, (−) output from DAMP2c is inputted to (+) input of MN3, and (+) output from DAMP2c is inputted to (−) input of MN4. (+) output from MP4 and the like is fed back to (+) input of DAMP1a and DAMP2a, and (−) output of MP3 and the like is fed back to (−) input of DAMP1a and DAMP2a.

In such an ADD, a differential voltage from the RO1 is converted into a differential current by the MN5 and MN6, a differential voltage from the RO2 is converted into a differential current by the MN3 and MN4, and these differential currents are added in the common drains of MN3, MN5, and MP3 and the common drains of MN4, MN6, and MP4, and converted into a differential output voltage. The differential output voltages are fed back as differential input voltages of RO1 and RO2. In terms of polarity, for example, when ‘H’ is applied to (+) input of DAMP1a, ‘L’ is outputted from the (−) output of DAMP1c as the (+) input of MN5 in the ADD. Then, since the ‘L’ is outputted from the (+) output of MP4 and the like, and the ‘L’ is fed back to the (+) input of DAMP1a, oscillation occurs.

As described above, by applying a differential amplifier circuit to the oscillation circuit of FIG. 1, a jitter component of a clock waveform can be reduced as described in the first embodiment, and a clock waveform of higher speed and smaller amplitude can be generated in comparison with the case of applying a CMOS circuit and the like.

### Third Embodiment

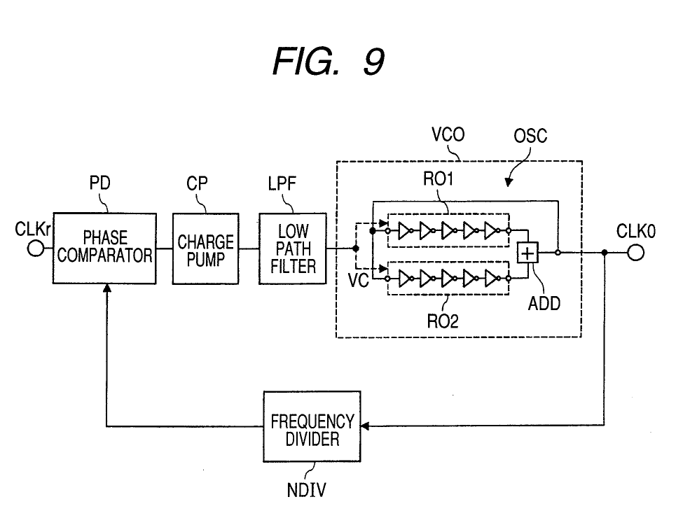

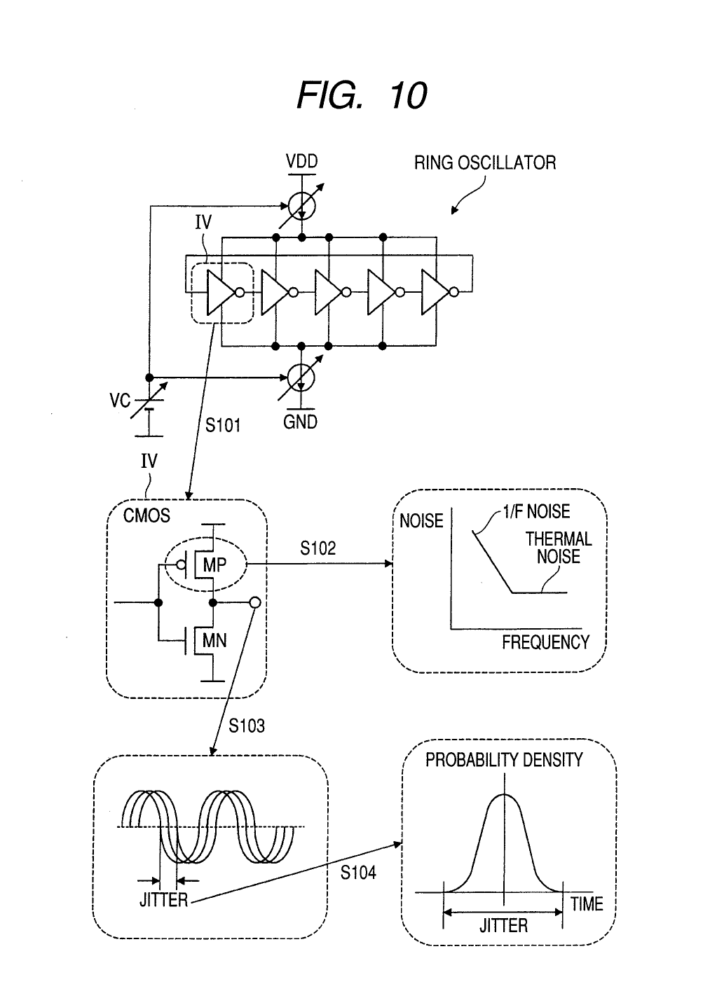

In the third embodiment, a description is made of a PLL (Phase Locked Loop) to which the construction examples of the first and second embodiments described previously are applied. FIG. 9 is a block diagram showing an example of the construction of an oscillation circuit of a third embodiment of the present invention. The oscillation circuit (PLL circuit) shown in FIG. 9 includes a phase comparator PD, a charge pump circuit CP, a low path filter LPF, a voltage controlled oscillation circuit VCO, and a frequency divider NDIV, and the oscillation circuit OSC described in the first and second embodiments is applied to the VCO.

An output clock signal CLKo from the voltage controlled oscillation circuit VCO is frequency-divided to a specific ratio by the frequency divider NDIV before being inputted to the phase comparator PD. The PD compares advancing conditions of phases from the output of the NDIV and a reference clock signal CLKr, and controls the charge pump circuit CP according to a result of the comparison. The CP outputs a charge current or discharge current according to a result of the phase comparison. The low path filter LPF smoothes the charge/discharge current from the CP and the voltage of a capacitor (not shown) within it is controlled by the charge current or discharge current. A voltage of the capacitor becomes a variable voltage source VC shown in the first and second embodiments, and the oscillation frequency of the oscillation circuit OSC within the VCO is controlled according to the VC. Finally, the oscillation frequency converges to an oscillation frequency in which the output of NDIV and the phase of CLKr match.

Such a PLL circuit is widely used in various equipments such as personal computers, server devices, and communication network equipments. Although use of the PLL circuit allows the phase of an output clock signal CLKo to be approximately matched to the phase of a reference clock signal CLKr, strictly, a dispersion caused by a jitter component of the VCO occurs in the phase of CLKo. Accordingly, by applying the oscillation circuit OSC of this embodiment to the VCO, the phase dispersion of CLKo is reduced, and a more accurate clock signal can be generated.

Hereinbefore, although the invention made by the inventors of the present invention has been described in detail based on the preferred embodiments, it goes without saying that the present invention is not limited to the preferred embodiments, but may be modified in various ways without changing the main purports of the present invention.

For example, in the construction example of FIG. 8, as shown in FIG. 4, by connecting the outputs of the ring oscillator units RO1 and RO2 with each other, an adding unit may be realized. In this case, in the construction example of FIG. 8, (−) output of RO_O1 is connected with (−) output of RO_O2, (+) output of RO_O1 is connected with (+) output of RO_O2, (−) output of the common connection is fed back to (+) input of RO_O1 and RO_O2, and (+) output of common connection is fed back to (−) input of RO_O1 and RO_O2.

The oscillation circuit of the present invention can apply widely to all systems that generate a clock signal by a ring oscillator circuit.

What is claimed is:

1. An oscillation circuit comprising:
N (N≧2) delay circuit units each including cascade-connected inverter circuits of an odd number of stages between an input node and an output node;
an adding unit that adds signals of the respective output nodes of the N delay circuit units; and
a feedback loop that feeds an addition result in the adding unit in common back to the respective input nodes of the delay circuit units.

2. The oscillation circuit according to claim 1,
wherein the adding unit connects the respective output nodes of the N delay circuits in common.

3. The oscillation circuit according to claim 1,
wherein the inverter circuits of an odd number of stages are formed by CMOS process.

4. The oscillation circuit according to claim 3,
wherein each of the inverter circuits of an odd number of stages is a CMOS differential amplifier circuit.

5. The oscillation circuit according to claim 4,
wherein the adding unit includes:
N transistor pairs to which differential output signals are respectively inputted from the N delay circuit units; and
a load circuit which is provided in common to the N transistor pairs and one end of which is connected to a differential output node that outputs the addition result, and
wherein the N transistor pairs are connected in parallel to the differential output node.

6. The oscillation circuit according to claim 1,
wherein the N delay circuit units further include a means that variably sets delay time of the inverter circuits of an odd number of stages.

7. An oscillation circuit comprising:
a voltage controlled oscillation unit that outputs a clock signal of a frequency corresponding to a control voltage;
a phase comparing unit that compares the phase of a clock signal outputted from the voltage control oscillation part and phase of a reference clock signal inputted from the outside;
a charge pump unit that generates electrical a charge/discharge current according to a phase comparison result in the phase comparing unit; and
a filter unit that stores a charge consequent on the charge/discharge current in a capacitor, and generates the control voltage to the voltage controlled oscillation unit,
wherein the voltage controlled oscillation unit includes:
first and second delay circuit units each including cascade-connected inverter circuits of an odd number of stages between an input node and an output node;
an adding unit that adds a signal of an output node of the first delay circuit unit and a signal of an output node of the second delay circuit unit;
a loopback loop that feeds an addition result in the adding unit in common back to an input node of the first delay circuit unit and an input node of the second delay circuit unit; and
a means that variably sets an operation current of the inverter circuits of an odd number of stages according to the control voltage.

8. The oscillation circuit according to claim 7,
wherein the adding unit connects in common the output node of the first delay circuit unit and the output node of the second delay circuit unit.

9. The oscillation circuit according to claim 7,
wherein the inverter circuits of an odd number of stages are formed by CMOS process.
